(19) United States
(12) Patent Application Publication
(10) Pub. No.: US 2017/0271560 A1
(43) Pub. Date: Sep. 21, 2017

(54) A NOVEL LED SUPPORT STRUCTURE

(71) Applicant: SHENZHEN JINGTAI CO., LTD., Shenzhen, Guangdong (CN)

(72) Inventors: Wen GONG, Shenzhen, Guangdong (CN); Pengrui SHAO, Shenzhen, Guangdong (CN); Jiaomin ZHOU, Shenzhen. Guangdong (CN)

(21) Appl. No.: 15/532,139

(22) PCT Filed: May 12, 2015
(86) PCT No.: PCT/CN2015/078770

§ 371 Date: Jun. 1, 2017

(30) Foreign Application Priority Data
Dec. 1, 2014 (CN) 201410708590.3

(51) Int. Cl. H01L 33/48; H01L 23/00; H01L 25/075; H01L 33/56; H01L 33/62; H01L 33/60

(52) U.S. Cl. CPC H01L 33/486; H01L 33/62; H01L 33/60; H01L 25/0753; H01L 33/56; H01L 24/48; H01L 2933/0058; H01L 2224/48091

(57) ABSTRACT

The invention discloses a novel LED support structure, including a metal support terminal; an LED chip fixed on the metal support terminal; a bonding wire for connecting the surface of the metal support terminal with the LED chip; and a packaging adhesive for protecting the LED chip. The invention further includes a plastic material covered on the surface of the metal support terminal; and a plastic material reflector cup for coating the metal support terminal. The metal support terminal includes a metal pin embedded in the plastic material reflector cup and a metal tube pin disposed outside the plastic material reflector cup, wherein the metal pin is provided with a functional zone and a non-functional zone.

### FIELD OF THE INVENTION

The present invention relates to the field of LED support technologies, and more particularly, to a novel LED support structure.

### BACKGROUND OF THE INVENTION

With the quick development of indoor and outdoor LED display application technology and lighting technology, a display screen surface-mounted LED device is used at present, but its performances cannot satisfy the using requirements of the market, particularly on the aspect of reliability.

A display screen and lighting used surface-mounted LED device, particularly an outdoor LED device requires a very high environment adaptivity, and needs to have excellent moisture resistance as well as high and low temperature resistance performances. However, the LED display screen still maintains a higher failure rate at present, and one of the causes is that a packaging adhesive is separated from the material in a reflector cup. However, vulcanization and failure phenomenon also present in lighting products. The tightness of a pin at the junction of a support terminal and a plastic material is one of the causes for the vulcanization and failure. Because the LED device is packaged and shaped by multiple raw materials, but the thermal expansion coefficients of each material subjected to a high temperature environment are different, which causes that the junction between the packaging adhesive and a metal sheet in the reflector cup is easy to separate, thus causing fracture to a bonding wire which connects the support lead frame of the LED chip or causing failure due to moisture entering into the device. Usually, the area of a metal zone at the bottom of the reflector cup occupies most area. The bonding performance between the metal and the adhesive is not strong by analyzing from the material behaviors. Therefore, during moisture absorption and heat expansion and cold contraction, the adhesive and the metal will separate usually, so that the bonding wire is fractured or the chip is pulled out to cause failure. While the poor bonding tightness of the support terminal and the plastics causes external sulfur element and oxygen to enter the cup body from the support pin and react with a silver layer on the surface of the terminal to become black.

Therefore, a problem to be urgently solved by those skilled in the art is how to solve the poor moisture resistance and poor leak tightness of the LED product, and improve the reliability of the LED product.

### SUMMARY OF THE INVENTION

In light of this, the present invention provides a novel LED support structure, which not only improves the tightness of the LED structure by increasing the bonding area between the plastic material and the packaging adhesive, but also improves the moisture resistance and reliability of the LED product by covering a gap at the junction with the metal pin using the plastic material, and prolongs the service life of the LED product.

In order to achieve the above objectives, the present invention is emboded by the follow technical solution:

A novel LED support structure includes a metal support terminal; an LED chip fixed on the metal support terminal; a bonding wire for connecting the surface of the metal support terminal with the LED chip; and a packaging adhesive for protecting the LED chip. The invention further includes a plastic material covered on the surface of the metal support terminal; and a plastic material reflector cup for coating the metal support terminal. The metal support terminal includes a metal pin embedded in the plastic material reflector cup and a metal tube pin disposed outside the plastic material reflector cup, wherein the metal pin is provided with a functional zone and a non-functional zone.

Preferably, in the novel LED support structure, the material of the metal support terminal may be a copper material, an iron material or an aluminum material; moreover, the surface of the metal support terminal is coated by one or a mixture of more of gold, silver, tin and nickel.

Preferably, in the novel LED support structure, the area of the plastic material in the plastic material reflector cup is increased by injecting a layer of plastic material on the surface of the non-functional zone of the metal pin through the cooperation of an injection molding machine and a jig, the plastic material covers a gap at the junction with the functional zone of the metal pin, and meanwhile, the shape of the plastic material is determined according to the size of the LED chip and the connecting manner of the bonding wire, which may be round, square, rhombus and irregular shape, and the plastic material may be one or a mixture of more of PPA, PCT, EMC and SMC.

Preferably, in the novel LED support structure, the plastic material of the non-functional zone of the metal pin is combined with the packaging adhesive for protecting the LED chip in case of not affecting the binding of the LED chip and the connecting of the bonding wire.

Preferably, in the novel LED support structure, the packed height of the plastic material of the non-functional zone of the metal pin ranges from 0.03 mm to 1.0 mm, and is higher than that of the functional zone of the metal pin; meanwhile, the packed height of the plastic material of each non-functional zone is an irregular plane, and an inclination angle of the portion contacted with the functional zone ranges from 30 degrees to 90 degrees.

Preferably, in the novel LED support structure, the shape of a base formed by the combination of the metal support terminal and the plastic material reflector cup may be a cube, a cuboid, a cylinder, or other irregular shape.

Preferably, in the novel LED support structure, the entire shape of the plastic material reflector cup may be an irregular shape, the opening of the cup may be round, square or square with four round corners, the inner wall of the cup may be a regular or irregular shape, and meanwhile, the material of the plastic material reflector cup may be one or a mixture of more of PPA, PCT, EMC and SMC.

Preferably, in the novel LED support structure, the bonding wire may be one or a mixture of more of a gold wire, a copper wire, a silver wire, an aluminum wire, a silver-wrapped-in-gold wire and an alloy wire.

Preferably, in the novel LED support structure, the LED chip may be a single chip, double chips and multiple chips, and the light emitting color may be one or a mixture of more of single color, double colors, and multiple colors.

Preferably, in the novel LED support structure, the packaging adhesive may be epoxy resin, silicone resin and silica gel, and the inside of the packaging adhesive may also be added with diffusion powder or phosphor powder made of silicon dioxide and silica, and the component of the phosphor powder may be nitride, silicate, chromium potassium and chromium lutetium.

It is known from the above technical solution that, compared with the prior art, the present invention provides a heat dissipation problem in case of not affecting the energizing of the LED device, so as to maximize the bonding area between the plastic material in the cup body at the bottom of the plastic material reflector cup and the packaging adhesive, and improve the sealing property of the LED product; meanwhile, the plane structure design of the functional zone of a conventional LED support is changed, and the bonding performance between the packaging adhesive and the zone of the plastic material reflector cup is improved by increasing the bonding area between the plastic material and the packaging adhesive; moreover, the plastic material of the non-functional zone of the metal pin covers the gap at the junction of the functional zone, which reduces the speed for water vapor to infiltrate from the junction of the metal pin and the plastic, which really improves the moisture resistance and sealing property of the LED product from structure, realizes high reliability of the LED product, and prolongs the service life of the LED product.

### BRIEF DESCRIPTION OF THE DRAWINGS

In order to explain the technical solutions in the embodiments of the invention or in the related art more clearly, the drawings used in the descriptions of the embodiments or the related art will be simply introduced hereinafter. It is apparent that the drawings described hereinafter are merely some embodiments of the invention, and those having ordinary sills in the art may also obtain other drawings according to these drawings provided without going through creative work.

FIG. 1 is a structure diagram of a conventional LED support structure;

FIG. 2 is a structure diagram of the present invention; and

FIG. 3 is a structure diagram of a tube pin of the present invention.

### Explanation of Numerals in the Figures

| | |
|---|---|
| 1′ refers to metal support terminal; | 2′ refers to LED chip; |
| 3′ refers to bonding wire; | 4′ refers to packaging adhesive; |
| 5′ refers to plastic material; | 6′ refers to plastic material |
| and 11′ refers to metal pin; | reflector cup; |
| 1 refers to metal support terminal; | 2 refers to LED chip; |
| 3 refers to bonding wire; | 4 refers to packaging adhesive; |
| 5 refers to plastic material; | 6 refers to plastic material |
| 11 refers to metal pin; | reflector cup; |
| | 12 refers to metal tube pin. |

### DETAILED DESCRIPTION OF THE PREFERRED EMBODIMENTS

Further illustrative explanations will be made clearly and completely to the technical solutions in the embodiments of the invention hereinafter with reference to the accompanying drawings in the embodiments of the invention. Apparently, the embodiments described are merely partial embodiments of the present invention, rather than all embodiments. Other embodiments derive by those having ordinary skills in the art on the basis of the embodiments of the invention without going through creative efforts shall all fall within the protection scope of the present invention.

Embodiments of the present invention provide a novel LED support structure, which not only improves the tightness of the LED structure by increasing the bonding area between the plastic material and the packaging adhesive, but also improves the moisture resistance and reliability of the LED product by covering a gap at the junction with the metal pin using the plastic material, and prolongs the service life of the LED product.

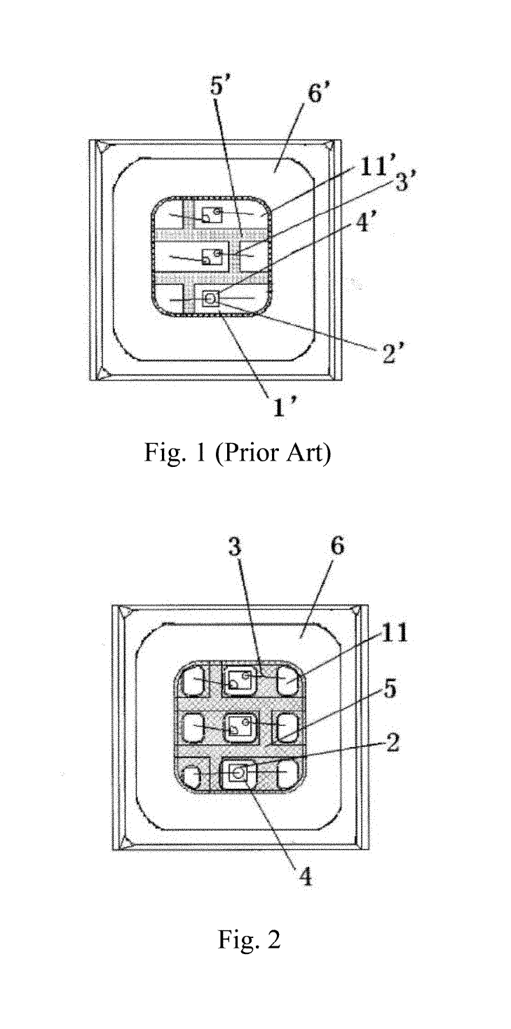

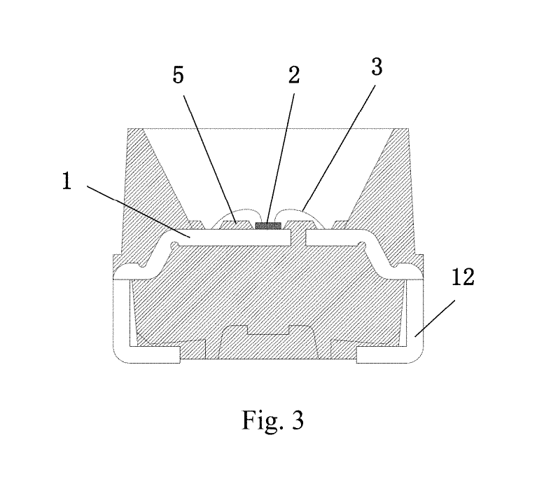

Explanation will be given with reference to the FIG. 1, FIG. 2 and FIG. 3 of the Description hereinafter. The present invention is a novel LED support structure, which concretely includes: a metal support terminal 1; an LED chip 2 fixed on the metal support terminal 1; a bonding wire 3 for connecting the surface of the metal support terminal 1 with the LED chip 2; and a packaging adhesive 4 for protecting the LED chip 2. The invention further includes a plastic material 5 covered on the surface of the metal support terminal 1; and plastic material reflector cup 6 for coating the metal support terminal 1. The metal support terminal 1 includes a metal pin 11 embedded in the plastic material reflector cup 6 and a metal tube pin 12 disposed outside the plastic material reflector cup 6, wherein the metal pin 11 is provided with a functional zone and a non-functional zone.

In order to further optimize the foregoing technical solution, the material of the metal support terminal 1 may be a copper material, an iron material or an aluminum material; moreover, the surface of the metal support terminal 1 is coated by one or a mixture of more of gold, silver, tin and nickel. In order to further optimize the foregoing technical solution, the area of the plastic material in the plastic material reflector cup 6 is increased by injecting a layer of plastic material on the surface of the non-functional zone of the metal pin 11 through the cooperation of an injection molding machine and a jig, and the plastic material covers a gap at the junction with the functional zone of the metal pin 11, which can reduce the speed for the water vapor to infiltrate from the junction of the metal tube pin 12 and the plastic material, and improve the moisture resistance of the product; and meanwhile, the shape of the plastic material is determined according to the size of the LED chip 2 and the connecting manner of the bonding wire 3, which may be round, square, rhombus and irregular shape, and the plastic material may be one or a mixture of more of PPA, PCT, EMC and SMC.

In order to further optimize the foregoing technical solution, the plastic material of the non-functional zone of the metal pin 11 is combined with the packaging adhesive 4 for protecting the LED chip 2 in case of not affecting the binding of the LED chip 2 and the connecting of the bonding wire 3, which maximizes the bonding area between the plastic material in the plastic material reflector cup 6 and the packaging adhesive 4, and meanwhile ensures to not reduce the actual area of the metal sheet in the plastic material reflector cup, increases the bonding performance between the packaging adhesive 4 and the zone of the plastic material reflector cup 6, and improves the tightness of the product.

In order to further optimize the foregoing technical solution, the packed height of the plastic material of the non-functional zone of the metal pin 11 ranges from 0.03 mm to 1.0 mm, and is higher than that of the functional zone; meanwhile, the packed height of the plastic material of each non-functional zone is an irregular plane, and an inclination angle of the portion contacted with the functional zone ranges from 30 degrees to 90 degrees.

In order to further optimize the foregoing technical solution, the shape of a base formed by the combination of the metal support terminal 1 and the plastic material reflector cup 6 may be a cube, a cuboid, a cylinder, or other irregular shape.

In order to further optimize the foregoing technical solution, the entire shape of the plastic material reflector cup 6 may be an irregular shape, the opening of the cup may be round, square or square with four round corners, and the inner wall of the cup may be a regular or irregular shape.

In order to further optimize the foregoing technical solution, the material of the plastic material reflector cup 6 may be one or a mixture of more of PPA, PCT, EMC and SMC.

In order to further optimize the foregoing technical solution, the bonding wire 3 may be one or a mixture of more of a gold wire, a copper wire, a silver wire, an aluminum wire, a silver-wrapped-in-gold wire and an alloy wire.

In order to further optimize the foregoing technical solution, the LED chip 2 may be a single chip, double chips and multiple chips, and the light emitting color may be one or a mixture of more of single color, double colors, and multiple colors.

In order to further optimize the foregoing technical solution, the packaging adhesive 4 may be epoxy resin, silicone resin and silica gel, and the inside of the packaging adhesive may also be added with diffusion powder or phosphor powder made of silicon dioxide and silica, and the component of the phosphor powder may be nitride, silicate, chromium potassium and chromium lutetium.

Each embodiment in the description is described using a progressive manner, and each highlights differences thereof from others. For the similar portions of the embodiments, please refer to each other. With regard to the embodiments of the device, a simple description is given since they are corresponding to the method disclosed in the embodiments, please refer to the explanations about the method for the related portions.

The above descriptions on the disclosed embodiments enable those skilled in the art can realize or use the present invention. Various modifications on these embodiments are apparent for those skilled in the art, and general principles defined herein may be realized in other embodiments without departing from the spirit or scope of the present invention. Accordingly, the present invention will not be limited to these embodiments shown herein, but is to be accorded with the widest scope consistent with the principles and novel features disclosed herein.

What is claimed is:

1. A novel LED support structure, comprising: a metal support terminal (1); an LED chip (2) fixed on the metal support terminal (1); a bonding wire (3) for connecting the surface of the metal support terminal (1) with the LED chip (2); and a packaging adhesive (4) for protecting the LED chip (2); and further comprising a plastic material (5) covered on the surface of the metal support terminal (1); and a plastic material reflector cup (6) for coating the metal support terminal (1); the metal support terminal (1) includes a metal pin (11) embedded in the plastic material reflector cup (6) and a metal tube pin (12) disposed outside the plastic material reflector cup (6), wherein the metal pin (11) is provided with a functional zone and a non-functional zone.

2. The novel LED support structure according to claim 1, wherein the material of the metal support terminal (1) may be a copper material, an iron material or an aluminum material; moreover, the surface of the metal support terminal (1) is coated by one or a mixture of more of gold, silver, tin and nickel.

3. The novel LED support structure according to claim 1, wherein the area of the plastic material in the plastic material reflector cup (6) is increased by injecting a layer of plastic material on the surface of the non-functional zone of the metal pin (11) through the cooperation of an injection molding machine and a jig, the plastic material covers a gap at the junction with the functional zone of the metal pin (11), and meanwhile, the shape of the plastic material is determined according to the size of the LED chip (2) and the connecting manner of the bonding wire (3), which may be round, square, rhombus and irregular shape, and the plastic material may be one or a mixture of more of PPA, PCT, EMC and SMC.

4. The novel LED support structure according to claim 1, wherein the plastic material of the non-functional zone of the metal pin (11) is combined with the packaging adhesive (4) for protecting the LED chip (2) in case of not affecting the binding of the LED chip (2) and the connecting of the bonding wire (3).

5. The novel LED support structure according to claim 1, wherein the packed height of the plastic material of the non-functional zone of the metal pin (11) ranges from 0.03 mm to 1.0 mm, and is higher than that of the functional zone of the metal pin (11); meanwhile, the packed height of the plastic material of each non-functional zone is an irregular plane, and an inclination angle of the portion contacted with the functional zone ranges from 30 degrees to 90 degrees.

6. The novel LED support structure according to claim 1, wherein the shape of a base formed by the combination of the metal support terminal (1) and the plastic material reflector cup (6) may be a cube, a cuboid, a cylinder, or other irregular shape.

7. The novel LED support structure according to claim 1, wherein the entire shape of the plastic material reflector cup (6) may be an irregular shape, the opening of the cup may be round, square or square with four round corners, the inner wall of the cup may be a regular or irregular shape, and meanwhile, the material of the plastic material reflector cup (6) may be one or a mixture of more of PPA, PCT, EMC and SMC.

8. The novel LED support structure according to claim 1, wherein the bonding wire (3) may be one or a mixture of more of a gold wire, a copper wire, a silver wire, an aluminum wire, a silver-wrapped-in-gold wire and an alloy wire.

9. A manufacture method for the novel LED support of claim 1, wherein the LED chip (2) may be a single chip, double chips and multiple chips, and the light emitting color may be one or a mixture of more of single color, double colors, and multiple colors.

10. The novel LED support structure according to claim 1, wherein the packaging adhesive (4) may be epoxy resin, silicone resin and silica gel, and the inside of the packaging adhesive may also be added with diffusion powder or phosphor powder made of silicon dioxide and silica, and the component of the phosphor powder may be nitride, silicate, chromium potassium and chromium lutetium.

11. The novel LED support structure according to claim 3, wherein the plastic material of the non-functional zone of the metal pin (11) is combined with the packaging adhesive (4) for protecting the LED chip (2) in case of not affecting the binding of the LED chip (2) and the connecting of the bonding wire (3).
